(19) United States
(12) Patent Application Publication
(10) Pub. No.: US 2013/0087193 A1
(43) Pub. Date: Apr. 11, 2013

(54) SOLAR CELL UNIT

(71) Applicants: Hideomi Yui, Osaka-shi (JP); Tsuyoshi Maeda, Osaka-shi (JP); Hideki Uchida, Osaka-shi (JP); Kyohko Azumada, Osaka-shi (JP)

(72) Inventors: Hideomi Yui, Osaka-shi (JP); Tsuyoshi Maeda, Osaka-shi (JP); Hideki Uchida, Osaka-shi (JP); Kyohko Azumada, Osaka-shi (JP)

(73) Assignee: SHARP KABUSHIKI KAISHA, Osaka-shi, Osaka (JP)

(21) Appl. No.: 13/704,410

(22) PCT Filed: Apr. 28, 2011
(86) PCT No.: PCT/JP2011/060437

§ 371 Date: Dec. 14, 2012

(30) Foreign Application Priority Data
Jun. 15, 2010 (JP) 2010-136408

(51) Int. Cl. H01L 31/055

(52) U.S. Cl. CPC H01L 31/055
USPC 136/257

(57) ABSTRACT

A solar cell unit (100) of the present invention includes (i) a fluorescence converging plate (2) that contains fluorescent materials (6) for absorbing invisible light and then emitting invisible light and (ii) a solar cell (4) provided on an end surface (2a) of the fluorescence converging plate (2) so as to have a light receiving surface which faces the ends surface (2a). When the fluorescence converging plate (2) is irradiated with external light, the fluorescent materials (6) emit invisible light which is then reflected in the fluorescence converging plate (2) and thereafter converged onto the end surface (2a). The solar cell (4) carries out electric power generation by use of fluorescence converged onto the end surface (2a) of the fluorescence converging plate (2). Conversely, visible light, with which the fluorescence converging plate (2) is irradiated, is transmitted through the fluorescence converging plate (2) without being absorbed by the fluorescent materials (6). The invisible light emitted from the fluorescent materials (6) is ultraviolet light or infrared light, and is therefore invisible to human eyes. This causes the fluorescence converging plate (2) to be perceived as having color close to transparent in a case where the fluorescence converging plate (2) is observed from a side opposite from a main surface irradiated with the light.

### TECHNICAL FIELD

The present invention relates to a solar cell unit.

### BACKGROUND ART

Solar cells have been put to widespread use. Among them, in recent years, it is becoming more and more common to provide solar cells on a building in order to generate electric power to be consumed in the building.

However, there are limits as to installation locations of conventional solar cells. For example, conventional silicon solar cells, which have been predominantly used, generate electric power by directly absorbing visible light mainly having a wavelength of 500 mm to 800 mm. Therefore, the conventional silicon solar cells do not let through the incident light. This limits installation locations of the conventional solar cells to locations where (i) the solar cells can receive sunlight and (ii) no problem will be created even if the sunlight is blocked from reaching backsides of the solar cells. Additionally, the conventional solar cells have large light receiving surfaces so as to generate a relatively large amount of electric power. As such, if the conventional solar cells are provided so as to be subjected to public exposure, then the view around them will be ruined.

In view of the circumstances, solar cell modules of see-through types have been recently developed. These types of solar cell modules are each produced by, for example, forming solar cells on a glass substrate and then forming numerous transparent openings in the solar cells. This causes outside light, which have entered from a glass-substrate side, to pass through the transparent openings as it is. It is therefore possible for the solar cell modules to be see-through.

Patent Literature 1 discloses a technology for preventing, while supplying light energy to a solar cell, the solar cell from being externally visible. According to the technology, specifically, a diffusing-transmitting layer is provided on a front side of the solar cell to receive light which enters from the front side. The diffusing-transmitting layer contains light emitting materials that absorb incident light whose wavelength falls in a predetermined wavelength range, and then emit light. Part of the light emitted from the light emitting materials is subjected to diffuse reflection so as to illuminate the exterior of the solar cell while another part of the light reaches the solar cell to contribute to electric power generation.

### CITATION LIST

### Patent Literatures

Patent Literature 1

PCT International Publication WO 95/17015 (Publication Date: Jun. 22, 1995)

### SUMMARY OF INVENTION

### Technical Problem

With the conventional solar cell modules of see-through types, however, there still remains a problem of low light-transmissivity in locations where the solar cells are provided. Therefore, the solar cell modules still fail to sufficiently reduce their visibility.

Additionally, the technology disclosed in Patent Literature 1 is required to configure the diffusing-transmitting layer to be thick in order to completely conceal the solar cell. This unfortunately makes it difficult to supply a sufficient amount of light energy to the solar cell. Moreover, the technology does not address the problem that the solar cell blocks light, and therefore merely has limited applications.

In view of the circumstances, an object of the present invention is to achieve a solar cell unit that suitably fulfills a function of a solar cell while being difficult to recognize from outside.

### Solution to Problem

In order to attain the object, a solar cell unit in accordance with the present invention includes: a fluorescence converging plate including (i) a light guide plate for guiding light therein to an end surface thereof and (ii) fluorescent materials which absorb first invisible light which enters or has entered the light guide plate and then emit second invisible light differing in wavelength from the first invisible light; and a solar cell provided on an end surface of the fluorescence converging plate so as to have a light receiving surface which faces the end surface.

According to the configuration, the fluorescence converging plate includes the light guide plate and the fluorescent materials. The fluorescent materials can be dispersed in the light guide plate or contained in a layer to be provided outside the light guide plate. When the fluorescence converging plate is irradiated with light, the fluorescent materials absorb first invisible light of the light, and then emit, in isotropic directions, second invisible light differing in wavelength from the first invisible light. The “invisible light” here means ultraviolet light or infrared light.

Second invisible light, which has been emitted (i) from the fluorescent materials and (ii) at an angle equal to or greater than the critical angle for total reflection with respect to main surfaces of the fluorescence converging plate, is subjected to total reflection in the fluorescence converging plate and then guided to the end surface. That is, it is second invisible light that is converged onto the end surface. The solar cell is provided so as to have its light receiving surface face the end surface, and is therefore able to carry out electric power generation by use of the second invisible light thus converged.

According to the configuration, visible light, of the light with which the fluorescence converging plate is irradiated, is transmitted through the fluorescence converging plate without being absorbed by the fluorescent materials. Even in a case where part of the invisible light emitted from the fluorescent materials is emitted out of the fluorescence converging plate without being reflected in the fluorescence converging plate, such light is invisible to human eyes. This causes the fluorescence converging plate to be perceived as having color close to transparent in a case where the fluorescence converging plate is observed from a side opposite from the main surface irradiated with the light.

Thus, the fluorescence converging plate, which makes up the majority of the solar cell unit, is nearly transparent. Therefore, it is possible to make the solar cell unit difficult to recognize from outside while a function of the solar cell is suitably fulfilled. This makes it possible to (i) provide a solar cell unit where installation of a solar cell unit was not a preferred option before and therefore (ii) increase the freedom of a location of a solar cell unit.

### Advantageous Effects of Invention

A solar cell unit in accordance with the present invention includes: a fluorescence converging plate including (i) a light guide plate for guiding light therein to an end surface thereof and (ii) fluorescent materials which absorb first invisible light which enters or has entered the light guide plate and then emit second invisible light differing in wavelength from the first invisible light; and a solar cell provided on an end surface of the fluorescence converging plate so as to have a light receiving surface which faces the end surface. Therefore, it is possible to achieve a solar cell unit that, while suitably carrying out electric power generation, is difficult recognize from outside.

### BRIEF DESCRIPTION OF DRAWINGS

FIG. 1 is a cross-sectional view schematically illustrating a solar cell unit in accordance with Embodiment 1 of the present invention.

FIG. 2 is a graph illustrating how a wavelength of light is related to its visibility.

FIG. 3 is a cross-sectional view illustrating a configuration of a window employing the solar cell unit illustrated in FIG. 1.

FIG. 4 is a set of views (a) and (b), (a) illustrating an example of how the window is installed, and (b) enlarging (a).

FIG. 5 is a cross-sectional view schematically illustrating a solar cell unit in accordance with Embodiment 2 of the present invention.

FIG. 6 is an exploded perspective view illustrating the solar cell unit illustrated in FIG. 5.

FIG. 7 is a view for illustrating replacement of a fluorescent film.

FIG. 8 is a cross-sectional view schematically illustrating a solar cell unit in accordance with Embodiment 3 of the present invention.

FIG. 9 is a set of cross-sectional views (a) and (b) illustrating modifications of the solar cell unit illustrated in FIG. 8.

FIG. 10 is a graph illustrating (i) a fluorescent material's light emission strength with respect to a wavelength of light and (ii) a spectral sensitivity of a wide bandgap semiconductor to the wavelength of the light.

### DESCRIPTION OF EMBODIMENTS

### Embodiment 1

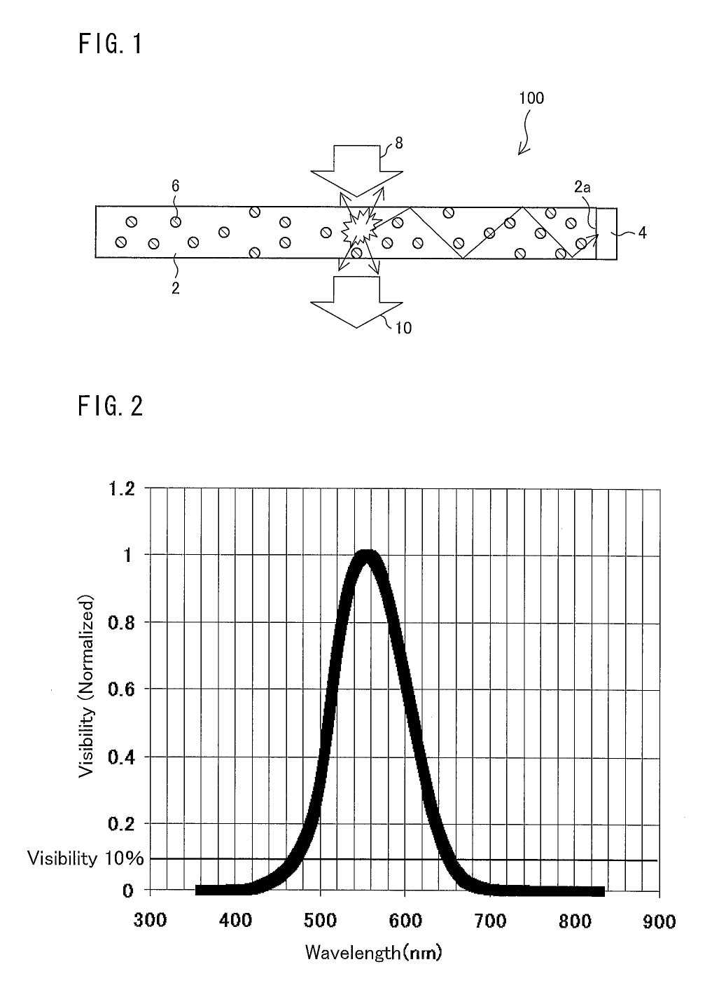

The following description will discuss Embodiment 1 of the present invention with reference to FIGS. 1 and 2.

First, a configuration of a solar cell unit 100 of Embodiment 1 will be schematically described below with reference to FIG. 1. The solar cell unit 100 includes a fluorescence converging plate 2 and a solar cell 4.

The fluorescence converging plate 2 is a light guide plate having fluorescent materials 6 dispersed therein. The fluorescence converging plate 2 can be prepared by dispersing the fluorescent materials 6 in a transparent material such as resin or glass.

Each of the fluorescent materials 6 is a fluorescent dye. The fluorescent dye is subjected to a transition to an excited state upon reception of invisible light contained in sun light, and, as it returns to a ground state which is more stable than the excited state, emits invisible light having a wavelength corresponding to an energy difference between the excited state and the ground state. In other words, each fluorescent material 6 first absorbs first invisible light and then emits second invisible light differing in wavelength from the first invisible light.

Note that, in the present specification, the term “invisible light” refers to any light except for visible light, examples of which invisible light include ultraviolet light and infrared light. In the present specification, however, “ultraviolet light ” and “infrared light ” are not strictly limited in their wavelength ranges, but are to include light having a wavelength falling in a near-ultraviolet range or a near-infrared range, which light is difficult to detect with human eyes.

To be specific, in a case where each fluorescent material emits ultraviolet light, an emission wavelength of the ultraviolet light has its peak at preferably not more than 470 nm, and, more preferably, not more than 400 nm. On the other hand, in a case where each fluorescent material 6 emits infrared light, an emission wavelength of the infrared light has its peak at preferably not less than 650 nm, and, more preferably, not less than 700 nm.

In a case where the emission wavelength of each fluorescent material 6 has its peak at not more than 470 nm or not less than 650 nm, the visibility of light emitted from the fluorescent material 6 is not more than 10%. Therefore, the light is difficult to detect with human eyes. In a case where the emission wavelength of each fluorescent material 6 has its peak at not more than 400 nm or not less than 700 nm, the visibility of light emitted from the fluorescent material 6 is close to 0. Therefore, the light is hardly visible to human eyes. Note that, on the premise that a wavelength of 555 nm having the greatest impact on human eyes is represented as a reference value 1, the term “visibility” is (i) calculated by the ratio of such a wavelength to other wavelengths and (ii) described by the degree of impact of those wavelengths (see FIG. 2).

Examples of the fluorescent materials 6 for emitting ultraviolet light encompass Lumogen F Violet 570 (absorption wavelength: 378 nm, light emission wavelength: 413 nm) (manufactured by BASF SE). Also, examples of the fluorescent materials 6 emitting light whose wavelength falls in the vicinity of the ultraviolet region encompass (i) Lumogen F Yellow 083 (absorption wavelength: 476 nm, light emission wavelength: 490 nm) and (ii) Lumogen F Yellow 170 (absorption wavelength: 505 nm, light emission wavelength: 528 nm).

On the other hand, examples of the fluorescent materials 6 for emitting infrared light encompass LiNdxYb₁₋ₓP₄O₁₂ (see International Publication WO/2009/011188).

A well-known solar cell can be employed as a solar cell 4, and there is no particular limitation in the selection. The solar cell 4 need only be provided on an end surface 2a of the fluorescence converging plate 2 so as to have a light receiving surface which faces the end surface 2a. The solar cell 4 can be optically attached to the fluorescence converging plate 2 via, for example, an adhesive layer (not illustrated) such as an αGEL (registered trademark: TAICA Corporation). It is preferable that the thickness of the adhesive is thinnest possible.

Note that the solar cell 4 is attached to the end surface 2a, which is one of the end surfaces of the fluorescence converging plate 2 (see FIG. 1). However, the present invention is not limited to such, provided that the solar cell 4 is attached to at least one end surface of the fluorescence converging plate 2.

The solar cell unit 100 is prepared by the following steps (i) through (iii): (i) preparing an acrylic plate (250 mm×250 mm ×10 mm) in which fluorescent dye Lumogen F Violet 570 (light emission wavelength: 413 nm, manufactured by BASF SE) are dispersed, (ii) optically attaching amorphous silicon solar cells to four end surfaces of the acrylic plate with the use of an αGEL (registered trademark: TAICA Corporation), and then (iii) connecting the solar cells in series. Note that these specific numbers are merely one example, and can be altered in many ways.

Next, a light converging structure of the solar cell unit 100 will be described below with further reference to FIG. 1.

To begin with, at least one of two main surfaces of the fluorescence converging plate 2 is configured to receive sun light. In the following description, for convenience, an arrow 8 illustrated in FIG. 1 indicates a direction of sun light irradiation.

The fluorescent materials 6 contained in the fluorescence converging plate 2 absorb ultraviolet light or infrared light contained in sun light, and then emit fluorescence (ultraviolet light or infrared light having differing wavelengths) in isotropic directions.

Fluorescence, which has been emitted (i) from the fluorescent materials 6 in the fluorescence converging plate 2 and (ii) at an angle equal to or greater than a critical angle for total reflection with respect to the top and bottom surfaces of the fluorescence converging plate 2, is subjected to total reflection repeatedly in the fluorescence converging plate 2 so as to be converged onto the end surface 2a. The solar cell 4 can generate electric power by use of the fluorescence thus converged onto the end surface 2a.

On the other hand, fluorescence, which (i) has been emitted from the fluorescent materials 6 and (ii) does not meet a condition for the total reflection, is emitted from the top or bottom surface. The fluorescence thus emitted is either ultraviolet light or infrared light, and its visibility is therefore low.

Of the sunlight with which the top surface of the fluorescence converging plate 2 is irradiated, light whose wavelength is outside a wavelength range in which light is absorbed by the fluorescent materials 6 (i.e. visible light other than ultraviolet light and infrared light) is transmitted through the fluorescence converging plate 2 (see an arrow 10). This causes the fluorescence converging plate 2 to be perceived as having color close to transparent in a case where the fluorescence converging plate 2 is observed from a bottom-surface side.

Thus, the fluorescence converging plate 2, which makes up the majority of the solar cell unit 100 in accordance with Embodiment 1, is nearly transparent. Therefore, the solar cell unit 100 can address the problem of external appearance while suitably fulfilling a function of a solar cell. This makes it possible to (i) provide a solar cell unit in a location where a solar cell unit was not a preferred option before and therefore (ii) increase the freedom of location of a solar cell unit.

Note that the solar cell 4's efficiency in light reception is increased by use of converged light. This allows the solar cell 4 to be downsized.

Types of Solar Cell 4

Fluorescence to be converged onto the end surface 2a of the fluorescence converging plate 2 is of a single wavelength. This makes it possible to further increase power generation efficiency of the solar cell unit 100 by employing, as a solar cell 4, a solar cell having an excellent sensitivity to the light emission wavelength of each fluorescent material 6.

For example, in a case where a fluorescent material (e.g. Lumogen F Violet 570 (emission wavelength: 413 nm)) that emits ultraviolet light is employed as a fluorescent material 6, it is preferable to use, as a solar cell 4, a wide bandgap semiconductor such as a titanium oxide (TiO₂) solar cell.

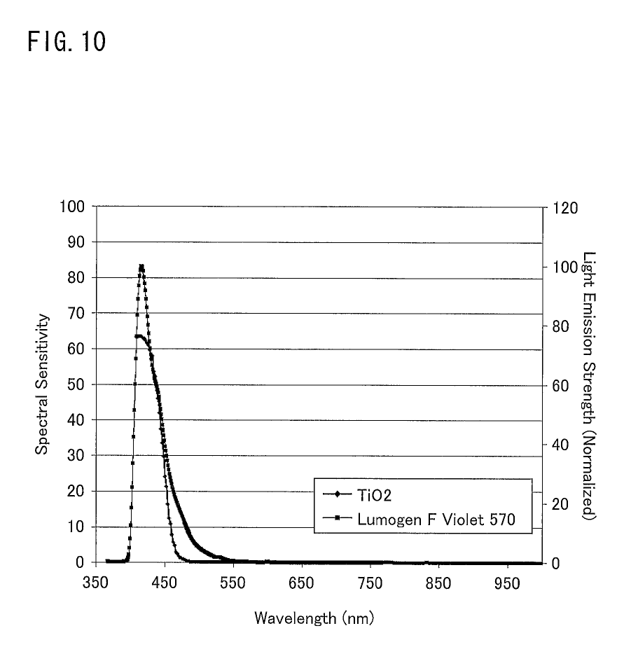

FIG. 10 is a graph illustrating (i) a luminescence intensity of a Lumogen F Violet 570 with respect to a wavelength of light and (ii) the spectral sensitivity of a TiO₂ solar cell to the wavelength of the light. As illustrated in FIG. 10, the spectral sensitivity of the TiO₂ solar cell overlaps with the peak of light emission strength of the Lumogen F Violet 570. This allows the TiO₂ solar cell to efficiently carry out a photovoltaic conversion of light emitted from the Lumogen F Violet 570.

The TiO₂ solar cell is not limited to a specific one. The TiO₂ solar cell can be prepared by, for example, the following steps (i) and (ii): (i) printing a TiO₂ powder on one of two transparent conductive glasses and (ii) keeping an electrolyte solution, which contains iodine ions, between the two transparent conductive glasses.

The wide bandgap semiconductor is not limited to a TiO₂ solar cell, but a ZnO solar cell and a CuAlO₂ solar cell can be employed as the wide bandgap semiconductor.

It is preferable to employ an amorphous silicon solar cell, in a case where a fluorescent material that emits light whose wavelength falls in the near-ultraviolet range (e.g. Lumogen F Yellow 083 (light emission wavelength: 490 nm) or Lumogen F Yellow 170 (light emission wavelength: 528 nm)) is employed as a fluorescent material 6.

In a case where a fluorescent dye that emits infrared light is employed as a fluorescent material 6, it is preferable to employ a monocrystalline solar cell or a compound solar cell.

Example Installation of Solar Cell Unit 100

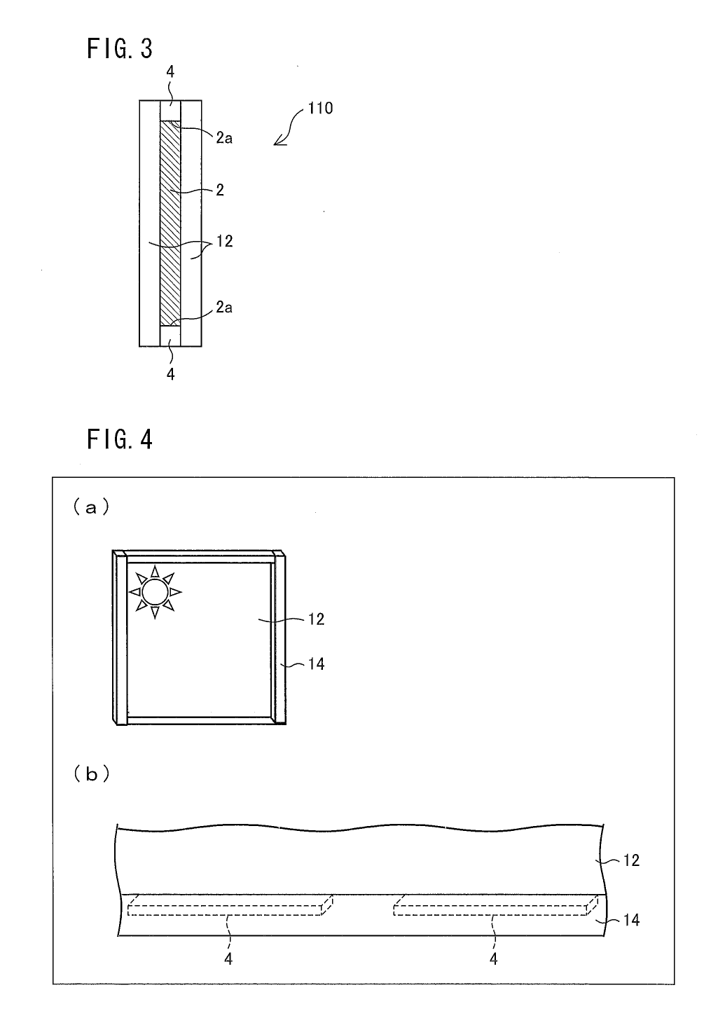

The solar cell unit 100 in accordance with Embodiment 1, because of its transparency, can be suitably provided on a windowpane on which a solar cell unit could not be provided before. An example installation will be described below with reference to FIGS. 3 and 4.

As illustrated in FIG. 3, the solar cell unit 100 is provided between a pair of glasses 12 so as to together make up a windowpane 110. As the pair of glasses 12, any commercially available ones can be employed. The pair of glasses 12 serves to protect the fluorescence converging plate 2.

As illustrated in (a) of FIG. 4, the windowpane 110 including the solar cell unit 100 is used as a window enclosed with a window frame 14. Note that it is preferable to provide the window frame 14 so as to conceal the solar cell 4 from outside (see (b) of FIG. 4). This prevents the solar cell 4 from being externally visible without requiring its transparency. As such, it is possible to design the solar cell 4 by preferentially taking into consideration factors, other than external appearance, such as production costs and power generation efficiency.

For example, a window including the solar cell unit 100 can be prepared by the following steps (i) through (iii): (i) providing an acrylic plate (700 mm×300 mm×10 mm), which contains ultraviolet fluorescent dye, between a pair of glasses (800 mm×800 mm) which is a commercial double-sliding window (In-Plus, TOSTEM brand, LIXIL Corporation), (ii) optically attaching amorphous silicon solar cells to four end surfaces of the acrylic plate with the use of an αGEL (registered trademark: TAICA Corporation), (iii) connecting the solar cells in series, and then (iv) enclosing the acrylics plate and the pair of glasses with a window frame. In so doing, conductive wires via which electric power is collected from the amorphous solar cells can be provided in a space inside the window frame.

With the configuration, (i) the solar cell unit 100 can be used as a window without any awkwardness and can properly generate electric power and (ii) the solar cell unit 100 can be installed without requiring an installation platform such as those used to install conventional solar cells.

Note that the installation of the solar cell unit 100 is not limited to the example above. For instance, it is possible to manufacture a fluorescence converging plate 2 by dispersing fluorescent materials 6 in a glass material, and then to use the fluorescence converging plate 2 itself as a windowpane 110.

### Embodiment 2

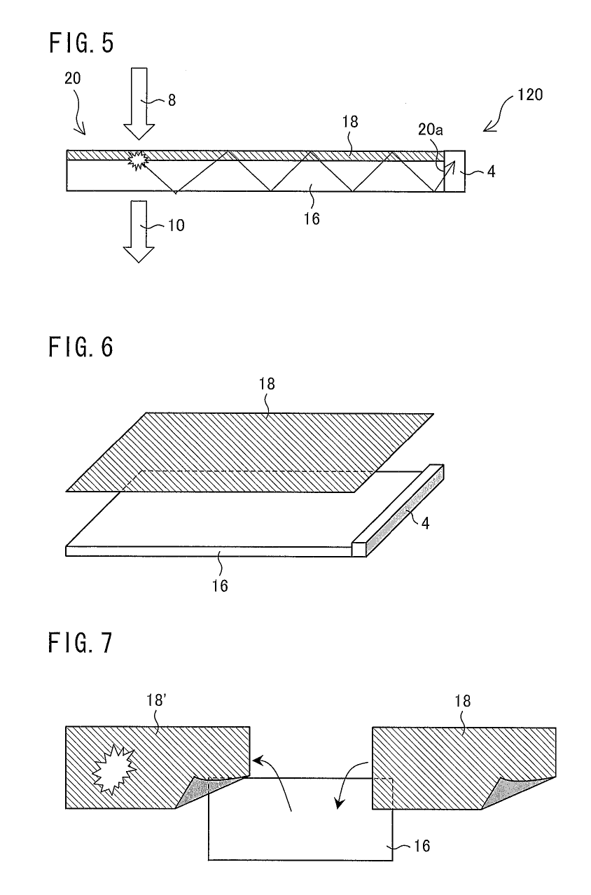

The following description will discuss Embodiment 2 of the present invention with reference to FIGS. 5 through 7. FIG. 5 is a cross-sectional view illustrating a solar cell unit 120 in accordance with Embodiment 2. FIG. 6 is an exploded perspective view illustrating the solar cell unit 120.

In Embodiment 2, constituent members, whose functions correspond to those of respective constituent members in Embodiment 1, are given the same reference numerals/signs accordingly, and their description will be omitted.

First, a configuration of the solar cell unit 120 of Embodiment 2 will be schematically described below. As illustrated in FIG. 5, the solar cell unit 120 includes a light guide plate 16, a fluorescent film (fluorescent layer) 18, and a solar cell 4.

In Embodiment 2, the light guide plate 16 and the fluorescent film 18 are stacked together so as to make up a fluorescence converging plate 20.

The light guide plate 16 is a transparent plate containing no fluorescent material therein, and can be made of a transparent material such as resin or glass.

The fluorescent film 18 is a film having fluorescent materials (not illustrated) dispersed therein. The fluorescent film 18 need only be provided by being optically attached to at least one of two main surfaces of the light guide plate 16. In Embodiment 2, the fluorescent film 18 is combined with a top surface of the light guide plate 16.

The solar cell 4 is provided at an end surface 20a of the fluorescence converging plate 20 so as to have a light receiving surface which faces the end surface 20a.

The solar cell unit 120 in accordance with Embodiment 2 can be prepared by the following steps (i) through (iv): for example, (i) preparing the fluorescent film 18 by expanding as well as thinning, down to a thickness of approximately 0.1 mm, a 10-mm-thick acrylic plate having fluorescent materials dispersed therein (such as the acrylic plate described in Embodiment 1), (ii) cutting the fluorescent film 18 out to a size of a glass measuring 250 mm×250 mm×10 mm, (iii) optically attaching, with the use of an αGEL (registered trademark: TAICA Corporation), the cut-out fluorescent film 18 to the glass, and (iv) optically attaching, with the use of an αGEL (registered trademark: TAICA Corporation), amorphous silicon solar cells to four end surfaces of the glass such that all the solar cells are connected in series. Note that these specific numbers are merely one example, and can be altered in many ways.

The fluorescence converging plate 20 of the solar cell unit 120 will be described below with further reference to FIG. 5.

First, when a top surface of the fluorescence converging plate 20 is irradiated with sunlight (in a direction illustrated by an arrow 8), the fluorescent materials in the fluorescent film 18 absorb, out of the sunlight, ultraviolet light or infrared light, and then emit fluorescence (ultraviolet light or infrared light) in isotropic directions.

Fluorescence, which has been emitted (i) from the fluorescent materials in the fluorescent film 18 and (ii) to a fluorescence-converging-plate-20 side, partly enters the fluorescence converging 20. Part of the fluorescence, which has entered the fluorescence converging plate 20, is guided through the light guide plate 16, and is then converged onto the end surface 20a. Another part of the fluorescence, which has entered the fluorescence converging plate 20, is guided through not only the light guide plate 16 but the entire fluorescence converging plate 20, and is then converged onto the end surface 20a. That is, the fluorescence converging plate 20 converges fluorescence onto its end surface 20a. The solar cell 4 can therefore carry out electric power generation by use of the fluorescence converged onto the end surface 20a of the fluorescence converging plate 20.

Meanwhile, fluorescence, which (i) has entered the fluorescence converging plate 20 and (ii) does not meet a condition for reflection inside the fluorescence converging plate 20, is emitted out from the top surface or a bottom surface of the fluorescence converging plate 20. The fluorescence thus emitted out is either ultraviolet light or infrared light, and its visibility is therefore low.

Of the sunlight with which the top surface of the fluorescence converging plate 20 is irradiated, light whose wavelength is outside a wavelength range in which light is absorbed by the fluorescent materials in the fluorescent film 18 (i.e. visible light other than ultraviolet light and infrared light) is transmitted through the fluorescence converging plate 20 (as illustrated by an arrow 10). This causes the fluorescence converging plate 20 to be perceived as having color close to transparent in a case where the fluorescence converging plate 20 is observed from a bottom-surface side.

Therefore, the solar cell unit 120 in accordance with Embodiment 2, as in Embodiment 1, can address the problem of external appearance while suitably fulfilling a function of a solar cell. This makes it possible to (i) provide a solar cell unit in a location where a solar cell unit was not a preferred option before and therefore (ii) increase the freedom of location of a solar cell unit.

Moreover, according to Embodiment 2, the maintenance of the solar cell unit 120 can be easily performed by replacing a damaged fluorescent film 18′ with a new fluorescent film 18 (see FIG. 7). Since the fluorescent film 18 is lightweight, it is also possible to expand the range of installation location in which the solar cell unit 120 can be installed.

Furthermore, according to Embodiment 2, the fluorescent materials are dispersed in the fluorescent film. This makes it possible to reduce the number of fluorescent materials to be used, as compared with Embodiment 1. Also, most of fluorescence, which is guided through the fluorescence converging plate 20, is guided through the transparent light guide plate 16. Therefore, it is possible to reduce, as compared with Embodiment 1, loss of light caused by the fluorescent materials' self-absorption of light.

### Embodiment 3

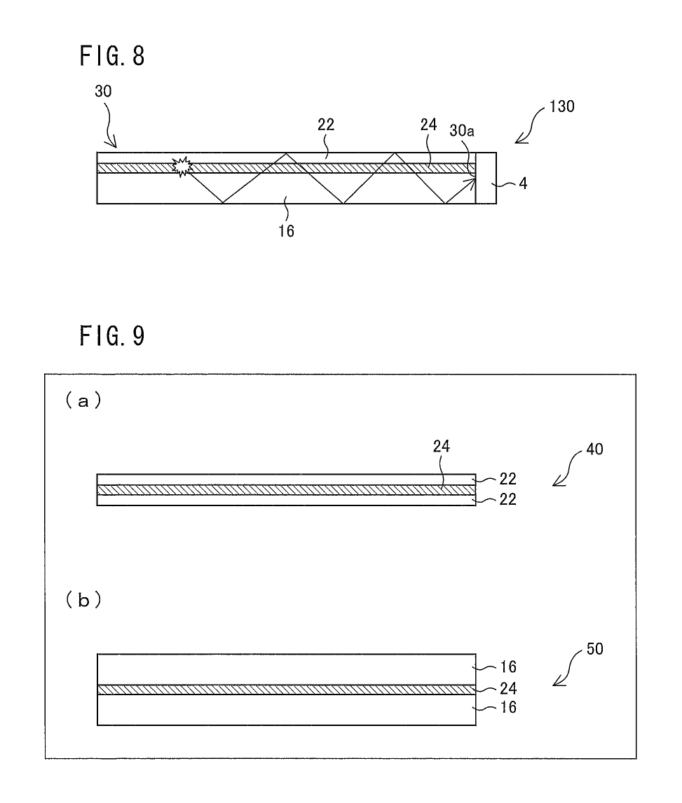

The following description will discuss Embodiment 3 of the present invention with reference to FIG. 8.

In Embodiment 3, constituent members whose functions correspond to those of respective constituent members in Embodiment 1 are given the same reference numerals/signs accordingly, and their description will be omitted.

First, a configuration of a solar cell unit 130 of Embodiment 3 will be schematically described below. As illustrated in FIG. 8, the solar cell unit 130 includes a light guide plate 16, a fluorescent resin (fluorescent layer) 24, a protection film (transparent layer) 22, and a solar cell 4.

In Embodiment 3, a fluorescence converging plate 30 is configured so that the light guide plate 16, the fluorescent resin 24, and the protection film 22 are stacked.

The protection film 22 is a transparent film, and functions to protect the fluorescent resin 24.

The fluorescent resin 24 is a resin having fluorescent materials (not illustrated) dispersed therein, and is sandwiched between the light guide plate 16 and the protection film 22 so as to serve as an adhesive attaching the light guide plate 16 and the protection film 22 to each other. The fluorescent materials are fluorescent dyes similar to the fluorescent materials 6 described in Embodiment 1. It is preferable to use, as a resin of which the fluorescent resin 24 is made, a transparent resin (i) capable of having fluorescent materials evenly dispersed therein and (ii) having low reactivity with fluorescent materials. For example, a thermosetting resin is preferable to a UV curing resin. This is because the UV curing resin is not matched up with fluorescent materials, so as to lessen light emission of the fluorescent materials. Examples of such a thermosetting resin encompass phenol resins such as an epoxy resin, a urea resin, and a melanin resin.

The solar cell unit 130 in accordance with Embodiment 3 can be prepared by the following steps (i) through (iii): for example, (i) evenly applying, over a glass measuring 250 mm×250 mm×10 mm, a phenol thermosetting resin (fluorescent resin) having fluorescent materials dispersed therein, (ii) attaching, to the fluorescent resin, a transparent protection film having a size identical as that of the glass, and (iii) optically attaching, with the use of an αGEL (registered trademark: TAICA Corporation), amorphous silicon solar cells to four end surfaces of the glass such that the all the solar cells are connected in series. Note that these specific numerals are illustrative only, and can therefore be altered in many ways.

In Embodiment 3 (as in Embodiment 2), the fluorescence converging plate 30 converges fluorescence (ultraviolet light or infrared light) onto its end surface 20a. The solar cell 4 carries out electric power generation by use of the fluorescence converged onto the end surface 30a of the fluorescence converging plate 30. The fluorescence converging plate 30 is perceived as having color close to transparent in a case where the fluorescence converging plate 30 is observed from a bottom-surface side.

Therefore, the solar cell unit 130 in accordance with Embodiment 3, as in Embodiments 1 and 2, can address the problem of external appearance while suitably fulfilling a function of a solar cell. This makes it possible to (i) provide a solar cell unit in a location where a solar cell unit was not a preferred option before and therefore (ii) increase the freedom of location of a solar cell unit.

Additionally, the solar cell unit 130 of Embodiment 3 is not limited to the configuration above. Rather, it is possible to variously achieve, in compliance with its installation location and intended use, the fluorescence converging plate 30 in which the fluorescent resin 24 is incorporated. For example, a fluorescence converging plate 40 in accordance with a modification can be configured such that a fluorescent resin 24 is sandwiched between two protection films 22(see (a) of FIG. 9). The protection films 22 function as respective light guide plates. Also, a fluorescence converging plate 50 in accordance with another modification can be configured such that a fluorescent resin 24 is sandwiched between two light guide plates 16 (see (b) of FIG. 9).

The present invention is not limited to the description of the Embodiments, but can be altered in many ways by a person skilled in the art within the scope of the claims. An embodiment derived from a proper combination of technical means disclosed in different embodiments is also encompassed in the technical scope of the present invention.

### Other Remarks

It is preferable to arrange a solar cell unit in accordance with the present invention such that: the light guide plate contains the fluorescent materials therein; and the fluorescent materials absorb light which has entered the light guide plate.

With the configuration, it is possible to achieve a fluorescence converging plate that is simple in structure. This makes it possible to suppress the solar cell unit's weight, material cost, and the like.

It is preferable that the solar cell unit in accordance with the present invention further includes a pair of glass plates sandwiching the light guide plate therebetween.

With the configuration, the light guide plate can be protected by the pair of glass plates. Also, a solar cell unit configured such can be suitably used as a window pane.

It is preferable to arrange the solar cell unit in accordance with the present invention such that: the fluorescence converging plate further includes a fluorescent layer which is provided on a main surface of the light guide plate and which contains the fluorescent materials therein; and the fluorescent materials absorb light which enters the light guide plate.

According to the configuration, second invisible light, which has been emitted from the fluorescent materials contained in the fluorescent layer, enters through the main surface of the light guide plate. Second invisible light, which has been emitted (i) from the fluorescent materials and (ii) at an angle equal to or greater than a critical angle for total reflection with respect to main surfaces of the fluorescence converging plate, is subjected to total reflection in the fluorescence converging plate and then guided to an end surface of the fluorescence converging plate. That is, it is second invisible light that is converged onto the end surface.

In a case where, for example, light is guided through a substance in which fluorescent materials are dispersed, loss of the light occurs as a result of the fluorescent materials' self-absorption of the light. With the configuration, however, (i) the solar cell unit can be configured such that the light guide plate contains no fluorescent materials therein and (ii) fluorescence emitted from the fluorescent materials can be guided mainly through the light guide plate. This makes it possible to reduce loss of light energy to be converged onto the end surface of the fluorescence converging plate.

It is preferable to arrange the solar cell unit in accordance with the present invention such that the fluorescent layer is a replaceable film.

With the configuration, it is possible to achieve the solar cell unit by such simple execution as combining a film and a solar cell with a light guide plate. This makes it possible to (i) expand installation locations where the solar cell unit can be installed and (ii) maintain the solar cell unit only by replacing the film.

It is preferable to arrange the solar cell unit in accordance with the present invention such that the fluorescence converging plate further includes a transparent layer provided such that the fluorescent layer is sandwiched between the transparent layer and the light guide plate.

According to the configuration, the fluorescence converging plate, in which fluorescence emitted from the fluorescent materials is guided, is made in a laminated structure made up of the light guide plate, the fluorescent layer, and the transparent layer. This allows second invisible light, which has been emitted from the fluorescent materials, to be not only reflected in the light guide plate but reflected inside the entire fluorescence converging plate so as to be guided to the end surface, for example. Thus, light converging efficiency is increased. Note that the transparent layer can be a transparent film or a glass plate, and can be flexibly selected in compliance with its installation location and intended use.

It is preferable to arrange the solar cell unit in accordance with the present invention such that: the first invisible light is ultraviolet light; and the solar cell is made from a wide bandgap semiconductor.

A light absorption range of a wide bandgap semiconductor is shifted toward an ultraviolet-light side. Therefore, according to the configuration, the solar cell's sensitivity to ultraviolet light emitted from the fluorescent materials is increased. This allows for an increase in photovoltaic conversion efficiency of the solar cell.

The solar cell unit in accordance with the present invention further includes a frame which surrounds end surfaces of the fluorescence converging plate and which covers the solar cell from outside.

In the configuration, the fluorescence converging plate is used as a part of a window. Note that the transparency of the fluorescence converging plate is ensured as described above. Note also that, since the solar cell is provided in a frame to be used as a window frame, a solar cell having favorable characteristics of a device, such as power generation efficiency and production costs etc., can be used as the solar cell without requiring its transparency. Therefore, the solar cell in accordance with the present invention can be used as a window without any awkwardness, and can properly generate electric power.

### Industrial Applicability

The present invention can be suitably applied to, for example, a solar cell to be provided on a window.

### Reference Signs List

2, 20 to 50 Fluorescence Converging Plate

2a, 20a, 30a End Surface

4 Solar Cell

6 Fluorescent Material

12 Pair of Glasses (glass plate)

14 Window Frame

16 Light Guide Plate

18 Fluorescent Film (fluorescent layer)

22 Protection Film (transparent layer)

24 Fluorescent Resin (fluorescent layer)

100, 120, 130 Solar Cell Unit

110 Windowpane

1. A solar cell unit comprising:
a fluorescence converging plate including (i) a light guide plate for guiding light therein to an end surface thereof and (ii) fluorescent materials which absorb first invisible light which enters or has entered the light guide plate and then emit second invisible light differing in wavelength from the first invisible light; and
a solar cell provided on an end surface of the fluorescence converging plate so as to have a light receiving surface which faces the end surface.

2. The solar cell unit as set forth in claim 1, wherein:
the light guide plate contains the fluorescent materials therein; and
the fluorescent materials absorb light which has entered the light guide plate.

3. A solar cell unit as set forth in claim 2, further comprising a pair of glass plates sandwiching the fluorescence converging plate therebetween.

4. The solar cell unit as set forth in claim 1, wherein:
the fluorescence converging plate further includes a fluorescent layer which is provided on a main surface of the light guide plate and which contains the fluorescent materials therein; and
the fluorescent materials absorb light which enters the light guide plate.

5. The solar cell unit as set forth in claim 4, wherein the fluorescent layer is a replaceable film.

6. The solar cell unit as set forth in claim 4, wherein the fluorescence converging plate further includes a transparent layer provided such that the fluorescent layer is sandwiched between the transparent layer and the light guide plate.

7. The solar cell unit as set forth in claim 1, wherein:
the first invisible light is ultraviolet light; and
the solar cell is made from a wide bandgap semiconductor.

8. A solar cell unit as set forth in claim 1, further comprising a frame which surrounds end surfaces of the fluorescence converging plate and which covers the solar cell from outside.
